(19) United States
(12) Patent Application Publication
(10) Pub. No.: US 2009/0223439 A1
(43) Pub. Date: Sep. 10, 2009

(54) Apparatuses and Methods for Growing Single Crystals

(75) Inventors: Mary Jane Shultz, Natick, MA (US); Irene Li, Cambridge, MA (US); Klaus Henning Groenzin, Bremen (DE)

Correspondence Address: MILLS & ONELLO LLP, ELEVEN BEACON STREET, SUITE 605, BOSTON, MA, 02108, US

(73) Assignee: TUFTS UNIVERSITY, Boston, MA (US)

(21) Appl. No.: 12/044,340

(22) Filed: Mar. 7, 2008

(51) Int. Cl. C30B 11/00

(52) U.S. Cl. 117/11; 117/200; 117/206

(57) ABSTRACT

In some embodiments, an apparatus configured to grow a single crystal includes a support configured to carry the single crystal. The support includes an end portion having variable widths along a length of the support. The apparatus can be used to grow, for example, large, high quality single crystals of ice in a short amount of time.

### TECHNICAL FIELD

The invention relates to apparatuses and methods for growing single crystals.

### BACKGROUND

A single crystal is a homogeneous solid in which the atoms, ions or molecules form an ordered and repeating three-dimensional pattern. The single crystal has a crystal lattice that is continuous and unbroken to the edges of the crystal, with minimal defects such as impurities or grain boundaries. In comparison, a polycrystalline solid includes a number of smaller crystals or crystallites separated by grain boundaries, and an amorphous solid has limited or no ordering of atoms, ions or molecules.

Certain single crystals are of interest to both academia and industry and have important applications. For example, single crystals of silicon and other semiconductors are used to manufacture integrated circuits, single crystals of sapphire and other materials are used for lasers and nonlinear optics, single crystals of fluorite are sometimes used in objective lenses of refracting telescopes, and single crystals of metals (such as superalloys) are used in some gas turbines. Furthermore, a single crystal of a material allows the atomic structure of the material to be determined (e.g., using X-ray diffraction), which otherwise would be difficult or impossible to determine. A single crystal of a material also allows the physical and chemical properties of the material to be characterized free of any influence from defects and along a selected direction. Some defects, such as grain boundaries, dislocations and impurities, can have significant effects on the physical, mechanical, and/or chemical properties of a material.

Single crystals can be formed or grown by building the crystal layer by layer. Exemplary techniques to produce large single crystals (or boules) include slowly drawing a rotating “seed crystal” from a molten bath of feeder material (for example, as in a Czochralski process and a Bridgeman technique). Some thin film deposition techniques, such as epitaxy, can form a new layer of material with the same structure on the surface of an existing single crystal.

### SUMMARY

The invention relates to apparatuses and methods for growing single crystals, such as, for example, single crystals of ice. The apparatuses and methods are capable of providing large, high quality crystals in a short time.

In one aspect, embodiments of the invention feature an apparatus configured to grow a single crystal including a support configured to carry the single crystal, the support including an end portion having variable widths along a length of the support.

Embodiments may include one or more of the following features. The end portion increases in width from a first end to a second end. The support further includes an elongated portion extending from the first end. The elongated portion is hollow. The support further includes an enlarged hollow portion attached to the elongated portion. The support further includes a narrowed portion adjacent to the second end. The end portion is hollow. The end portion has a first end and a second end, and the support further includes an elongated portion extending from the first end, an enlarged hollow portion attached to the elongated portion, and a narrowed portion adjacent to the second end. The end portion increases in width from the first end to the second end. The end portion, the elongated portion and the narrowed portion are hollow. The apparatus further includes a housing, and a non-moving fluid in the housing, wherein at least a portion of the support is in the housing. The apparatus further includes a moving fluid around at least a portion of the non-moving fluid. The apparatus further includes a barrier extending across an interior of the housing and having an opening, wherein the support is capable of passing through the opening. The non-moving fluid has a first temperature on a first side of the barrier, and a second temperature on a second side of the barrier. The first temperature is higher than a freezing point of the single crystal, and the second temperature is lower than the freezing point of the single crystal. The non-moving fluid includes ethylene glycol. The apparatus further includes a housing, at least a portion of the support being in the housing, and a fluid in the housing, the fluid comprising ethylene glycol and water. The fluid includes approximately 25% to approximately 35% by volume of ethylene glycol. The apparatus further includes a seed including ice in the support.

In another aspect, embodiments of the invention feature an apparatus configured to grow a single crystal including a support configured to carry the single crystal; a housing, at least a portion of the support being in the housing; and a non-moving fluid in the housing.

Embodiments may include one or more of the following features. The apparatus further includes a moving fluid around at least a portion of the non-moving fluid. The apparatus further includes a barrier extending across an interior of the housing and having an opening, wherein the support is capable of passing through the opening. The non-moving fluid has a first temperature on a first side of the barrier, and a second temperature on a second side of the barrier. The first temperature is higher than a freezing point of the single crystal, and the second temperature is lower than the freezing point of the single crystal. The non-moving fluid includes ethylene glycol. The apparatus further includes a seed including ice in the support.

In another aspect, embodiments of the invention feature an apparatus configured to grow a single crystal including a support configured to carry the single crystal; a housing, at least a portion of the support being in the housing; and a first fluid in the housing, the first fluid including ethylene glycol and water.

Embodiments may include one or more of the following features. The first fluid includes approximately 25% to approximately 35% by volume of ethylene glycol. The first fluid consists essentially of ethylene glycol and water. The first fluid is moving. The apparatus further includes a non-moving fluid around at least a portion of the support. The non-moving fluid includes ethylene glycol. The apparatus further includes a seed including ice in the support.

In another aspect, embodiments of the invention feature a method of growing a single crystal including growing the crystal in a support having an end portion having variable widths along a length of the support.

Embodiments may include one or more of the following features. The end portion increases in width from a first end to a second end. The support further includes an elongated portion extending from the first end. The elongated portion is hollow. The support further includes an enlarged hollow portion attached to the elongated portion. The support further includes a narrowed portion adjacent to the second end. The end portion is hollow. The end portion has a first end and a second end, and the support further includes an elongated portion extending from the first end, an enlarged hollow portion attached to the elongated portion, and a narrowed portion adjacent to the second end. The end portion increases in width from the first end to the second end. The end portion, the elongated portion and the narrowed portion are hollow. The method further includes contacting the support with a non-moving fluid. The method further includes moving a first fluid around at least a portion of the non-moving fluid. The method further includes passing a portion of the support from a first portion of the non-moving fluid having a first temperature to a second portion of the non-moving fluid having a second temperature. The method further includes passing the portion of the support through an opening of a barrier dividing the first and second portions of the non-moving fluid. The first temperature is higher than a freezing point of the single crystal, and the second temperature is lower than the freezing point of the single crystal. The non-moving fluid includes ethylene glycol. At least a portion of the support is in a housing containing a fluid including ethylene glycol and water. The fluid includes approximately 25% to approximately 35% by volume of ethylene glycol. The method further includes seeding ice in the support.

In another aspect, embodiments of the invention feature a method of growing a single crystal including growing the crystal in a support, at least a portion of the support being in a housing; and contacting the support to a non-moving fluid in the housing.

Embodiments may include one or more of the following features. The method further includes moving a fluid around at least a portion of the non-moving fluid. The method further includes extending a barrier across an interior of the housing, wherein the barrier has an opening, and the support is capable of passing through the opening. The non-moving fluid has a first temperature on a first side of the barrier, and a second temperature on a second side of the barrier. The first temperature is higher than a freezing point of the single crystal, and the second temperature is lower than the freezing point of the single crystal. The non-moving fluid includes ethylene glycol. The method further includes seeding ice in the support.

In another aspect, embodiments of the invention feature a method of growing a single crystal including growing the crystal on a support, at least a portion of the support being in a housing; and contacting the support to a first fluid in the housing, the first fluid including ethylene glycol.

Embodiments may include one or more of the following features. The first fluid consists essentially of ethylene glycol. The first fluid is non-moving. The method further includes moving a second fluid around at least a portion of the first fluid. The method further includes seeding ice in the support.

Other aspects, features and advantages will be apparent from the description of the embodiments thereof and from the claims.

### BRIEF DESCRIPTION OF DRAWINGS

FIG. 1 is a schematic diagram of an embodiment of an apparatus for growing single crystals.

FIG. 2 is a detailed view of an embodiment of a support for growing single crystals.

FIG. 3A is a picture of a slice of an ice crystal taken through crossed polarizers showing multiple domains with clearly visible grain boundaries; and FIG. 3B is a picture of a slice of an ice crystal taken through crossed polarizers showing a single-crystal specimen.

FIG. 4A is a conoscopic image of a single-crystal ice sample cut with the c-axis parallel to the viewing direction or perpendicular to the interface; and FIG. 4B is a conoscopic image of a single-crystal ice sample miscut by about 5°.

FIG. 5 is an image of an etch-pit pattern from a basal face of a single-crystal sample.

### DETAILED DESCRIPTION

The apparatuses and methods described herein can be used to grow single crystals, such as single crystals that grow uniaxially or at anisotropic growth rates from its melt or solution. Examples of materials for crystal growth include ice and bio-molecules (such as L-alanine).

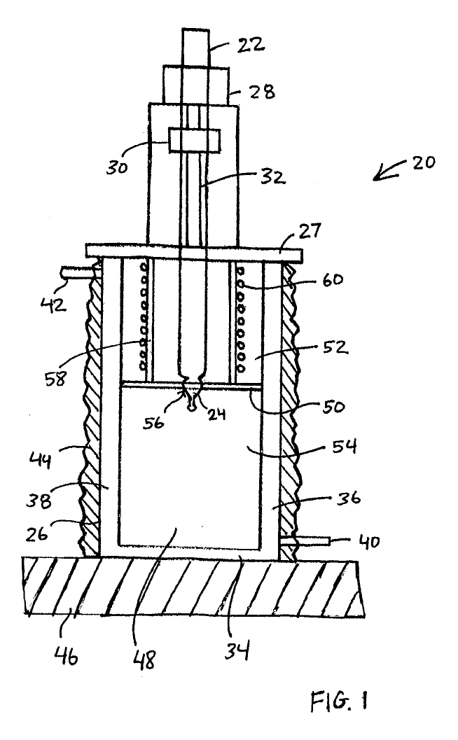

FIG. 1 shows an apparatus 20 capable of being used to grow single crystals. Apparatus 20 includes a glass support 22 configured to carry a single crystal 24 that grows inside the glass support, and an enclosable cylindrical housing 26 into which a portion of the support can enter and in which the single crystal is grown. More specifically, housing 26 includes a cover 27 having an opening (not shown), and apparatus 20 includes a stepper motor 28, a PTFE holder 30 and a rail 32 that are configured to secure support 22 over cover 27 and to move the support through the opening of the cover. Rail 32 provides a track that guides the movement of support 22, and stepper motor 28 is capable of translating support 22 (as shown, vertically) at selected incremental distances and at selected rates.

Still referring to FIG. 1, housing 26 is configured to provide an environment that is conducive for growing high quality single crystals. In addition to cover 27, housing 26 includes a double-walled bottom 34 and double-walled side 36 (or sides for a non-cylindrical housing). Bottom 34 and side 36 are filled with a moving fluid 38 (such as a coolant) that is continuously introduced into and removed from the bottom and the side via an inlet 40 and an outlet 42, respectively. An example of a fluid (e.g., to grow a single crystal of ice) is a liquid mixture of ethylene glycol and water. On its exterior, side 36 of housing 26 is wrapped with insulation 44 to help maintain the selected temperatures of and in the housing. Housing 26 is also rested on a vibration isolation table 46 (such as a 10 ft×10 ft, 6,000 lb optical table) to reduce motion (e.g., vibration) from being transferred to the growing crystal 24 contained in the housing.

In its interior, housing 26 contains a non-moving fluid 48 (such as a liquid coolant) that surrounds and contacts the exterior surface of glass support 22. As used herein, “non-moving” means that no force is applied. For example, non-moving fluid 48 diffuses and may have some thermal convection due to temperature differences, but no force (e.g., agitation or perturbation) is applied to the fluid. In contrast, during operation of apparatus 20, fluid 38 in double-walled bottom 34 and side 36 is moving because the fluid flows as it is being continuously introduced and removed via inlet 40 and outlet 42. Without being bound by theory, it is believed that growing single crystals in a non-moving medium (such as non-moving fluid 48) facilitates growth of high quality single crystals with low defects.

To further facilitate good crystal growth, non-moving fluid 48 is maintained at different temperatures with selected profiles within housing 26. As shown, apparatus 20 includes a barrier 50 (e.g., a Lexan sheet) that extends across the interior of housing 26 to divide the interior into a first (as shown, top) side 52 and a second (as shown, bottom) side 54. Barrier 50 reduces mixing between first side 52 and second side 54 to help keep a sharp solidification zone, which helps to restrict the solidification zone of the growing crystal and help maintain the integrity of the growing crystal. In first side 52, apparatus 20 includes a metal (e.g., aluminum) cylinder 58 and a heating coil 60 configured to heat and/or to maintain fluid 48 in the first side at selected temperature(s). Barrier 50 includes an opening 56 through which support 22 can pass and fluid 48 can diffuse. Barrier 50, along with housing 26 and the other features in the housing, are designed to provide fluid 48 with a sharp solidification zone (e.g., 273K for growth of ice crystals) that is generally co-planar with the barrier and its opening 56, although the solidification zone can be thinner or thicker than the thickness of the barrier. The temperature of first side 52 (above the solidification zone) is kept higher than the temperature of second side 54 (below the solidification zone). Above the solidification zone (e.g., barrier 50), the temperature of fluid 48 increases with increasing distance from the solidification zone; and below the freezing zone (e.g., the barrier), the temperature of the fluid decreases with increasing distance from the solidification zone. For example, where the solidification zone is 273K (e.g., to grow ice crystals), the temperature of fluid 48 in first side 52 can increase from approximately 273K to approximately 277K with increasing distance from the solidification zone (e.g., barrier 50), and the temperature of the fluid in second side 54 can decrease from approximately 273K to approximately 263K with increasing distance from the solidification zone. Without being bound by theory, it is believed that growing single crystals through a temperature gradient with a sharp and narrow solidification zone facilitates growth of high quality single crystals with low defects. In some embodiments, the solidification zone has a thickness of approximately 0.1 mm to approximately 1 mm.

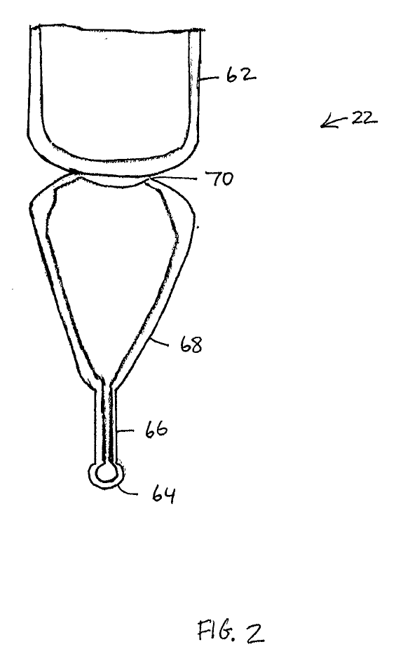

Referring now to FIG. 2, like other features of apparatus 20, support 22 is also designed to facilitate good crystal growth. As shown, support 22 has a hollow, generally cylindrical body 62 that is engaged at one end portion with stepper motor 28 such that the stepper motor can translate the support through opening 56. At its other end, where crystal 24 is grown, support 22 is configured so that crystal growth is seeded by only one crystal domain and so that only a single domain propagates toward body 62. More specifically, support 22 includes a bulb 64, a capillary 66 connected to the bulb, a crucible 68 connected to the capillary, and a neck 70 that joins the crucible to body 62. Bulb 64 is a generally spherical, hollow body that is used to seed single crystal 24. Capillary 66 is a hollow and generally cylindrical member that joins bulb 64 and crucible 68. Crucible 68 is a cone-like, hollow body that has tapered sidewalls. As shown, the outer width (e.g., outer diameter) of crucible 68 increases generally linearly from the end connected to capillary 66 to the end connected to neck 70, which is also hollow. Then, as crucible 68 approaches toward neck 70, the outer width of the crucible decreases until the crucible joins the neck. The inner volumes of bulb 64, capillary 66, crucible 68, neck 70, and body 62 are all in fluid communication. Without being bound by theory, it is believed that the tapered sides of crucible 68 allow certain domains (e.g., one domain) to grow, while physically eliminating other orientations. Crystals growing in directions that are not directed through neck 70 self-annihilate as they contact crucible 68, thus refining the growing crystal. Neck 70 allows crystals in the desired direction to pass. It is believed that neck 70 should not be too narrow, e.g., no smaller than approximately 2 mm) because further restriction may reintroduce random growth.

As an example, support 22 can have the following dimensions. The overall length of support 22 can be approximately 42 cm, with an inner diameter of 2 to 3 cm. Body 62 can have an average outer width or an outer diameter of approximately 3.5 cm, an average inner width or an inner diameter of approximately 2-3 cm, and a length of approximately 38 cm, as measured from neck 70 to the other end of the body. Neck 70 can have an average outer width or an outer diameter of approximately 12 mm, an average inner width or an inner diameter of approximately 6-7 mm, and a length of approximately 3 mm. Crucible 68 can have a length of approximately 32 mm. Over a length of approximately 10 mm, starting at the end where crucible 68 is connected to neck 70, the average outer width or the outer diameter can increase from approximately 9 mm to approximately 29 mm, and the average inner width or the inner diameter can increase from approximately 7 mm to approximately 27 mm. Then, over a length of approximately 25 mm, the average outer width or the outer diameter of crucible 68 can decrease from approximately 29 mm to approximately 9 mm, and the average inner width or the inner diameter can decrease from approximately 27 mm to approximately 7 mm as the crucible extends toward capillary 66. Capillary 66 (e.g., a 3 mm standard tube) can have an average outer width or an outer diameter of approximately 3 mm, an average inner width or an inner diameter of approximately 2 mm, and a length of approximately 4-8 mm. Bulb 64 can have an average outer width or an outer diameter of approximately 4 mm. In some embodiments, bulb 64 is approximately 25% larger than the outer width or outer diameter of capillary 66. In some embodiments, neck 70 is approximately 25% smaller than the largest inner width or diameter of crucible 68.

Referring again to FIG. 1, moving fluid 38 is chosen to accommodate the chiller temperature setting used to cool non-moving fluid 48, and the non-moving fluid is selected to provide low convection currents and reduced (e.g., minimized) thermal gradients, which further help to form a sharp and narrow solidification zone. As an example, to grow single crystals of ice, fluids 38, 48 can include (e.g., comprise or consist essentially of) a mixture of ethylene glycol and water. In some embodiments, fluids 38 and/or 48, independently, include approximately 25 to approximately 35 percent by volume of ethylene glycol, and approximately 65 to approximately 75 percent by volume of water. The concentration of ethylene glycol, by volume, can be greater than or equal to approximately 25%, approximately 27%, approximately 29%, approximately 31%, or approximately 33%; and/or less than or equal to approximately 35%, approximately 33%, approximately 31%, approximately 29%, or approximately 27%. The concentration of water, by volume, can be greater than or equal to approximately 65%, approximately 67%, approximately 69%, approximately 71%, or approximately 73%; and/or less than or equal to approximately 75%, approximately 73%, approximately 71%, approximately 69%, or approximately 67%. Non-moving fluid 48 can include (e.g., consists essentially of) neat ethylene glycol.

As indicated above, in other embodiments, the devices, apparatuses and methods described herein can be used to grow single crystals of other materials. Examples of materials include those whose crystals grow uniaxially, or differently in different crystallographic directions, such as biological compounds, e.g., L-alanine.

### EXAMPLE

The following example uses certain embodiments described above to grow high quality (e.g., strain free, free of line defects and grain boundaries) single crystals of ice in a short amount of time (e.g., in a few days). Slow growth can result in the c-axis oriented perpendicular to the axis of support 22, or parallel to the meniscus between ice and water (the growth front), which is maintained in a horizontal orientation. Careful control of growth conditions can result in crypto-morphological growth of singles crystals that are approximately 2.5 cm diameter by up to approximately 10 cm long, with single crystal domains in the range of approximately 50 cm³.

Support 22 is cleaned by soaking overnight in concentrated sulfuric acid mixed with NoChromix®. It is possible to shorten this time to 2 hours if a quick clean is all that is needed. Following the acid treatment, support 22 is soaked in nanopure (18 MΩ) water overnight. To remove residual acid trapped in support 22, water is drawn in by attaching the support via a side arm (e.g., attached 2.54 cm from the top of the support) to a dedicated vacuum line and then the water is expelled using a heat gun. Caution should be taken because the expulsion can be quite violent. This procedure is performed 3-4 times. Any residual acid can result in a freezing point depression, and an ice seed (described below) may not remain frozen at 273 K.

Support 22 is filled with nanopure (18 MΩ) water and left standing upright in a covered container for a day. Care is taken so that air bubbles are not trapped anywhere within support 22 (the growth tube). Prior to use, support 22 is again flushed 2-3 times. At all points, gloves are worn to reduce organic contamination. Neoprene stoppers, used to seal the top end of support 22 during the slow crystallization process, are stored in nanopure water until use.

The water in support 22 is degassed prior to crystallization by simultaneously pumping and sonicating for approximately 35 min. After degassing and sonication are complete, support 22 is sealed with paraffin. Experimentally, the growth rate is not as critical in producing high quality ice (i.e., larger domain size) as compared to other growth parameters. By controlling parameters to reduce vibrational noise, thermal convection, and water contaminants, e.g., gases and organics (described above), the production of single domain ice with dimensions of 2.54 cm diameter and 10.16 cm length can become routine. For example, through examining ice crystals grown under various conditions, reducing vibrations can be a very influential factor in producing single crystals. Accordingly, apparatus 20 includes a vibration isolation table (a large 10 ft, 6000 lbs optical table). Thermal convection can be reduced by pre-chilling the water for approximately 1 h; which was experimentally determined. Convection can also be reduced by barrier 50, which keeps fluid in the two sides 52, 54 from extensive mixing. Mixing or longer equilibration time (tested up to 24 h) can result in smaller domains. An objective is to have the water temperature stabilized at the desired temperature and to keep the solidification zone (or, in this example, the zero degree zone) sharp. The pre-chill temperature gradient is kept no warmer than 277 K where water is at its most dense. Following the hour pre-chill, bulb 64 is seeded and quickly placed back into position. The water is left to sit for 15 min to remove disturbances before initializing stepping (described below).

During crystal growth, apparatus 20 lowers the water-filled crucible 68 from a pre-chill zone (first side 52) kept above the freezing point (gradient from 273 K to 277 K) into a zone (second side 54) chilled below the freezing point (gradient from 273 to 263 K±2 K).

The pre-chill side 52 can be resistively heated by a Variac controller to maintain the temperature gradient range. The temperature inside pre-chill side 52 can be measured with a thermistor (Digikey GE thermistor:MA100 Series) to see if it is in the desired temperature range and that the range is stable. An exemplary range is 276.4 K near the top of the neat ethylene glycol and 272.1 K at the bottom of barrier 50 (a Lexan material). There is a certain amount of range flexibility with the constraint being that the fluid is below 277 K near the top. Maintaining a temperature slightly below 273 K at barrier 50 can be convenient for being able to visually situate bulb 64. The two sides 52, 54 are interconnected and contain pure ethylene glycol. These sides 52, 54 are isolated from a heat transfer fluid circulating to double-walled bottom and side 34, 36 from a chiller (RTE740 ThermoNESLABS). The heat transfer fluid is a 30:70 mixture ratio of ethylene glycol to water, which has a freezing point of 257 K. To accommodate a colder chiller temperature, the freezing point can be lowered by increasing the ethylene glycol percentage. The chiller is set to 261 K, which is a good approximation of the cold zone temperature to a tenth of a degree, and the temperature is allowed to stabilize for at most 3 hours. A toggle valve can be added to prevent the heat transfer fluid from flowing back into the chiller reservoir; when water condenses into the fluid over time, the viscosity is lowered, which can cause overflow.

For ease of setup, support 22 is first situated in apparatus 20 so bulb 64 is just slightly above the 273 K zone (273.2 K) and the position marked with tape before seeding. Seeding is done by dropping methanol on bulb 64 and touching it to dry ice for 5 sec. The seed is visible and should only cover about half bulb 64. Ice crystal 24 is seeded by polycrystalline ice at the end of bulb 64. Removal of ice crystal 24 can be done by hand warming support 22.

The rate of crystallization found to be most effective in terms of growing larger domains within a reasonable time frame is to let the ice form about 2.54 cm at 0.381μ/s and then to increase the rate to 0.781μ/s for the remaining 12.7 cm. The length of travel is approximately 15.24 cm. A stepper motor (BiStep2A Dual 2.0 Amp) and a motor controller (Peter Norberg Consulting) can be used to step a linear actuator with a resolution of 0.0006 in/step (Haydon Switch and Instrument). The full distance used correlates to 590,000 steps. Apparatus 20 can be controlled either manually or via computer.

Surface orientation and quality of the grown single crystal can be evaluated by etching with a 2% polyvinyl formal resin in ethylene dichloride, known as Formvar, pre-chilled to −12° C., and imaging with a cooled (−4° C.) optical microscope (Meji ML9300) interfaced with a digital camera (Pixelink firewire Model PL-A662). (See, e.g., Pamplin, B. R., Crystal Growth. 1^{st} ed.; Pergamon Press: Oxford, New York, 1975; Vol. 6.)

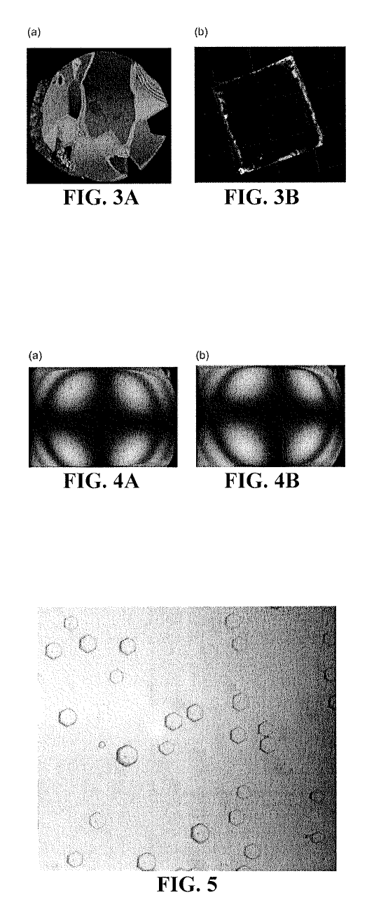

Orientation of the grown single crystal (e.g., the c-axis) can be confirmed using a Rigsby stage with cross polarizers (FIGS. 3A and 3B) and with conoscopy (FIGS. 4A and 4B). Ice is a weakly positive birefringent material with an ordinary index of refraction equal to 1.3091 and an extraordinary index equal to 1.3105. Although the birefringence is weak, it can be used not only to determine the orientation of the c-axis, but also to evaluate the quality of the ice crystal. FIGS. 3A and 3B show two different ice specimens viewed through crossed polarizers. If the crystal is oriented with the c-axis along the line-of-sight, the plane of the incident polarization is unchanged as the light travels through the ice. Since the polarizers are crossed, the crystal appears dark and remains so as it is rotated about the line-of-sight. If the c-axis is at even a slight an angle to the line-of-sight, the crystal alternately shows extinction and light as it is rotated. FIG. 3A shows an image of a multicrystalline sample with multiple domains and clearly visible grain boundaries. Regions that are dark in the shown orientation light up as the crystal is rotated, indicating that the c-axis is not aligned with the line-of-sight. In this sample, the c axes in the different domains are oriented nearly perpendicular to the line-of sight. The c-axis orientation of neighboring domains is oriented in distinct directions to the line-of-sight. A step pattern in the upper right corner of FIG. 3A is shown. In crystal growth, this pattern is referred to as hoppering, which indicates growth from a grain boundary and that the sample was grown too fast. (Id.) In contrast, FIG. 3B shows a single-crystalline sample. The entire sample remains dark when rotated between cross polarizers, indicating not only that the sample is a single crystal, but also that the c-axis is along the line of sight. For this example, the entire domain remains extinct as the crystal is rotated between cross polarizers, indicating that the c-axis is within 1° of the line of sight. (The lit fringes are due to machining of the sample and do not extend into the interior of the sample.)

Orientation of the c-axis along the line of sight can also determined by conoscopy. A conoscopic image is produced by a birefringent crystal when high angle fringe rays interfere with rays that are coaxial with the line-of-sight. The image is produced by placing the crystal between crossed polarizers, placing a large numerical aperture lens on the polarizer or holding the eye (or camera) extremely close to the lens. If the c-axis is along the line-of-sight, the conoscopic image is a dark cross centered among concentric interference rings. The arms of the dark cross are aligned with the two polarizers. The fringe rays have both o- and e-ray components. Interference is produced by the run-time difference between the fringe rays and the c-axis ray as the rays propagate through the crystal. Crystal imperfections, such as grain boundaries, blur the interference rings and distort the cross. Thus, the placement of the cross relative to the rings is a very sensitive measure for the orientation of the c-axis. When the c-axis aligned with the line of sight or perpendicular to the interface, the cross appears centered in the rings. When the c-axis is at an angle to the line of sight, the cross is off center.

FIGS. 4A and 4B show two conoscopic images of single-crystal ice samples. (The images are produced on a dark background due to the crossed polarizers; the dark background has been removed in order to show the image structure.) In FIG. 4A, the cross is located at the center of the concentric rings indicating that the crystal is cut with the c-axis parallel to the viewing direction or perpendicular to the interface. In FIG. 4B, the cross is shifted to the upper-right corner indicating that the crystal miscut by about 5° (Rigsby determination).

The surface of the crystal can also be characterized for defect density and impurity contamination by etching. FIG. 5 shows an etch-pit pattern from the basal face (clearly showing hexagonal features) of a poor quality single-crystal sample using Formvar. The image corresponds to a 0.67-mm×0.53-mm or 0.36 mm² area. Etch pits nucleate at surface defect sites. (See, e.g., Higuchi, K., The etching of ice crystals. Acta Metallurgica 1958, 6, 636-642; Sinha, N. K., Observation of basal dislocations in ice by etching and replicating. J. Glaciology 1978, 21, (number 85), 385-395; Barrette, P. D.; Sinha, N. K., Lattice rotation in a deformed ice crystal: A study by chemical etching and replication. Mat. Chem. Phys 1996, 44, 251-254; Kuroiwa, D., Surface topography of etched ice crystals observed by a scanning electron microscope. J. Glaciology 1969, 8, (number 54), 475-483; and Krausz, A. S.; Gold, L. W., Surface Features Observed During Thermal Etching of Ice. J. Coll. Interface Sci. 1967, 25, 255-262.) On strain-free crystals, these defects include either grain boundaries between single-crystal domains or point defects where screw dislocations emerge at the surface. In some embodiments, surfaces used for spectroscopic experiments must be free from grain boundaries and typically have a screw dislocation density of less than approximately 500 cm⁻².

All references, such as patents, patent applications, and publications, referred to above are incorporated by reference in their entirety.

Other embodiments are within the scope of the following claims.

What is claimed is:

1. An apparatus configured to grow a single crystal, comprising:
a support configured to carry the single crystal, the support comprising an end portion having variable widths along a length of the support.

2. The apparatus of claim 1, wherein the end portion increases in width from a first end to a second end.

3. The apparatus of claim 2, wherein the support further comprises an elongated portion extending from the first end.

4. The apparatus of claim 3, wherein the elongated portion is hollow.

5. The apparatus of claim 3, wherein the support further comprises an enlarged hollow portion attached to the elongated portion.

6. The apparatus of claim 2, wherein the support further comprises a narrowed portion adjacent to the second end.

7. The apparatus of claim 1, wherein the end portion is hollow.

8. The apparatus of claim 1, wherein the end portion has a first end and a second end, and the support further comprises an elongated portion extending from the first end, an enlarged hollow portion attached to the elongated portion, and a narrowed portion adjacent to the second end.

9. The apparatus of claim 8, wherein the end portion increases in width from the first end to the second end.

10. The apparatus of claim 8, wherein the end portion, the elongated portion and the narrowed portion are hollow.

11. The apparatus of claim 1, further comprising a housing, and a non-moving fluid in the housing, wherein at least a portion of the support is in the housing.

12. The apparatus of claim 11, further comprising a moving fluid around at least a portion of the non-moving fluid.

13. The apparatus of claim 11, further comprising a barrier extending across an interior of the housing and having an opening, wherein the support is capable of passing through the opening.

14. The apparatus of claim 13, wherein the non-moving fluid has a first temperature on a first side of the barrier, and a second temperature on a second side of the barrier.

15. The apparatus of claim 14, wherein the first temperature is higher than the freezing point of the single crystal, and the second temperature is lower than the freezing point of the single crystal.

16. The apparatus of claim 11, wherein the non-moving fluid comprises ethylene glycol.

17. The apparatus of claim 1, further comprising a housing, at least a portion of the support being in the housing, and a fluid in the housing, the fluid comprising ethylene glycol and water.

18. The apparatus of claim 17, wherein the fluid comprises approximately 25% to approximately 35% by volume of ethylene glycol.

19. The apparatus of claim 1, further comprising a seed comprising ice in the support.

20. An apparatus configured to grow a single crystal, comprising:
a support configured to carry the single crystal;
a housing, at least a portion of the support being in the housing; and
a non-moving fluid in the housing.

21. The apparatus of claim 20, further comprising a moving fluid around at least a portion of the non-moving fluid.

22. The apparatus of claim 20, further comprising a barrier extending across an interior of the housing and having an opening, wherein the support is capable of passing through the opening.

23. The apparatus of claim 22, wherein the non-moving fluid has a first temperature on a first side of the barrier, and a second temperature on a second side of the barrier.

24. The apparatus of claim 23, wherein the first temperature is higher than a freezing point of the single crystal, and the second temperature is lower than the freezing point of the single crystal.

25. The apparatus of claim 20, wherein the non-moving fluid comprises ethylene glycol.

26. The apparatus of claim 20, further comprising a seed comprising ice in the support.

27. An apparatus configured to grow a single crystal, comprising:
a support configured to carry the single crystal;
a housing, at least a portion of the support being in the housing; and
a first fluid around at least a portion of the support, the first fluid comprising ethylene glycol and water.

28. The apparatus of claim 27, wherein the first fluid comprises approximately 25% to approximately 35% by volume of ethylene glycol.

29. The apparatus of claim 27, wherein the first fluid consists essentially of ethylene glycol and water.

30. The apparatus of claim 27, wherein the first fluid is moving.

31. The apparatus of claim 27, further comprising a non-moving fluid around at least a portion of the support.

32. The apparatus of claim 31, wherein the non-moving fluid comprises ethylene glycol.

33. The apparatus of claim 27, further comprising a seed comprising ice in the support.

34. A method of growing a single crystal, comprising:
growing the crystal in a support comprising an end portion having variable widths along a length of the support.

35. The method of claim 34, wherein the end portion increases in width from a first end to a second end.

36. The method of claim 35, wherein the support further comprises an elongated portion extending from the first end.

37. The method of claim 36, wherein the elongated portion is hollow.

38. The method of claim 37, wherein the support further comprises an enlarged hollow portion attached to the elongated portion.

39. The method of claim 35, wherein the support further comprises a narrowed portion adjacent to the second end.

40. The method of claim 34, wherein the end portion is hollow.

41. The method of claim 34, wherein the end portion has a first end and a second end, and the support further comprises an elongated portion extending from the first end, an enlarged hollow portion attached to the elongated portion, and a narrowed portion adjacent to the second end.

42. The method of claim 41, wherein the end portion increases in width from the first end to the second end.

43. The method of claim 42, wherein the end portion, the elongated portion and the narrowed portion are hollow.

44. The method of claim 34, further comprising contacting the support with a non-moving fluid.

45. The method of claim 44, further comprising moving a first fluid around at least a portion of the non-moving fluid.

46. The method of claim 44, further comprising passing a portion of the support from a first portion of the non-moving fluid having a first temperature to a second portion of the non-moving fluid having a second temperature.

47. The method of claim 46, further comprising passing the portion of the support through an opening of a barrier dividing the first and second portions of the non-moving fluid.

48. The method of claim 46, wherein the first temperature is higher than a freezing point of the single crystal, and the second temperature is lower than the freezing point of the single crystal.

49. The method of claim 44, wherein the non-moving fluid comprises ethylene glycol.

50. The method of claim 34, wherein at least a portion of the support is in a housing containing a fluid comprising ethylene glycol and water.

51. The method of claim 51, wherein the fluid comprises approximately 25% to approximately 35% by volume of ethylene glycol.

52. The method of claim 34, further comprising seeding ice in the support.

53. A method of growing a single crystal, comprising:
growing the crystal in a support, at least a portion of the support being in a housing; and
contacting the support to a non-moving fluid in the housing.

54. The method of claim 53, further comprising moving a fluid around at least a portion of the non-moving fluid.

55. The method of claim 53, further comprising extending a barrier across an interior of the housing, wherein the barrier has an opening, and the support is capable of passing through the opening.

56. The method of claim 55, wherein the non-moving fluid has a first temperature on a first side of the barrier, and a second temperature on a second side of the barrier.

57. The method of claim 56, wherein the first temperature is higher than a freezing point of the single crystal, and the second temperature is lower than the freezing point of the single crystal.

58. The method of claim 53, wherein the non-moving fluid comprises ethylene glycol.

59. The method of claim 53, further comprising seeding ice in the support.

60. A method of growing a single crystal, comprising:
growing the crystal in a support, at least a portion of the support being in a housing; and
contacting the support to a first fluid in the housing, the first fluid comprising ethylene glycol.

61. The method of claim 60, wherein the first fluid consists essentially of ethylene glycol.

62. The method of claim 60, wherein the first fluid is non-moving.

63. The method of claim 60, further comprising moving a second fluid around at least a portion of the first fluid.

64. The method of claim 60, further comprising seeding ice in the support.
